(19) United States
(12) Patent Application Publication
(10) Pub. No.: US 2011/0155456 A1
(43) Pub. Date: Jun. 30, 2011

(54) JUNCTION BOX FOR SOLAR PANEL

(75) Inventors: Szu-Han Li, Zhongli City (TW); Hung-Ming Tseng, Taipei City (TW)

(73) Assignee: Du Pont Apollo Limited, Pak Shek Kok (HK)

(21) Appl. No.: 12/970,897

(22) Filed: Dec. 16, 2010

Related U.S. Application Data
(60) Provisional application No. 61/290,607, filed on Dec. 29, 2009.

(51) Int. Cl. H05K 5/00; B23P 19/04

(52) U.S. Cl. 174/565; 29/428

(57) ABSTRACT

A junction box for use in establishing electric connection between an electric cable and output terminals of a solar panel is provided. The junction box includes an elongate plastic housing and a metal frame. The elongate plastic housing is disposed along and sandwiches an edge of the solar panel, from which the output terminals of a solar panel extend out. The elongate plastic housing defines a passage, inside which the electric cable is connected with the output terminals of the solar panel. The metal frame fully encloses the elongate plastic housing.

### RELATED APPLICATIONS

This application claims priority to U.S. Provisional Application Ser. No. 61/290,607, filed Dec. 29, 2009, which is herein incorporated by reference.

### BACKGROUND

1. Field of Invention

The present invention relates to photovoltaic devices. More particularly, the present invention relates to a junction box for use with a flat photovoltaic panel.

2. Description of Related Art

The increasing scarcity and the realization of the ecological and safety problems associated with non-renewable energy reserves such as coal petroleum and uranium have made increased use of alternate energy resources such as photovoltaic energy. Photovoltaic energy use has been limited in the past to special application due to the high cost of manufacturing devices capable of producing significant amounts of photovoltaic energy. The development of depositing successive layers of amorphous semiconductor alloy material on a substrate to fabricate photovoltaic devices in mass production has greatly promoted the use of photovoltaic energy.

An electrical junction box is used in establishing electrical connection between an electric cable and output terminals of a solar panel. A conventional junction box is designed with a large profile and mounted under a solar panel. This conventional design makes all power cables grouped under the solar panel and the output terminals of the solar panel need to be connected with the junction box via additional cables, thereby makes the space under the solar panel crowded. What is needed is a low profile junction box with a durable and waterproof connection between the electric cable and the solar panel.

### SUMMARY

In accordance with an aspect of the present invention, a junction box for use in establishing electric connection between an electric cable and output terminals of a solar panel is provided. The junction box includes an elongate plastic housing and a metal frame. The elongate plastic housing is disposed along and sandwiches an edge of the solar panel, from which the output terminals of a solar panel extend out. The elongate plastic housing defines a passage, inside which the electric cable is connected with the output terminals of the solar panel. The metal frame fully encloses the elongate plastic housing.

According to one embodiment of the present invention, the elongate plastic housing comprises an elongate axis to be perpendicular to a direction along which the output terminals are disposed.

According to another embodiment of the present invention, the elongate plastic housing and the edge of the solar panel share an equal length.

According to another embodiment of the present invention, the elongate plastic housing consists of an upper member and a lower member, the solar panel is sandwiched between the upper and lower members.

According to another embodiment of the present invention, the upper member is secured to an upper glass substrate of the solar panel, the lower member is secured to a lower glass substrate of the solar panel.

According to another embodiment of the present invention, the elongate plastic housing is made from elastic plastic materials.

According to another embodiment of the present invention, the metal frame is made from aluminum.

According to another embodiment of the present invention, the metal frame consists of an upper frame and a lower frame.

In accordance with another aspect of the present invention, a method for assembling a junction box to a solar panel is provided. A lower member of an elongate plastic housing is attached to an edge of the solar panel. A sub-wire of a power cable is soldered to an end of output terminals of the solar panel. An upper member of the elongate plastic housing is attached to the edge of the solar panel. The upper member and the lower member are combined to sandwich the soldered interconnection between the power cable and the output terminals of the solar panel. A metal frame is assembled to fully enclose the elongate plastic housing.

According to one embodiment of the present invention, the method further includes the step of attaching the lower member of the elongate plastic housing to an edge of a lower glass substrate of the solar panel.

According to another embodiment of the present invention, the method further includes the step of using an adhesive to attach the lower member of the elongate plastic housing to the edge of the lower glass substrate of the solar panel.

According to another embodiment of the present invention, the method further includes the step of attaching the upper member of the elongate plastic housing to an edge of a lower glass substrate of the solar panel.

According to another embodiment of the present invention, the method further includes the step of using an adhesive to attach the upper member of the elongate plastic housing to the edge of the upper glass substrate of the solar panel.

According to another embodiment of the present invention, the elongate plastic housing is made from elastic plastic materials.

According to another embodiment of the present invention, the metal frame is made from aluminum.

According to another embodiment of the present invention, the method further includes the step of arranging the elongate plastic housing to have an elongate axis thereof to be perpendicular to a direction along which the output terminals are disposed.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a solar panel with a junction box attached to an edge thereof according to one preferred embodiment of this invention;

FIG. 2 illustrates a cross-sectional view taken along A-A′ in FIG. 1; and

FIG. 3 is a flowchart of a method for assembling a junction box to a solar panel according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

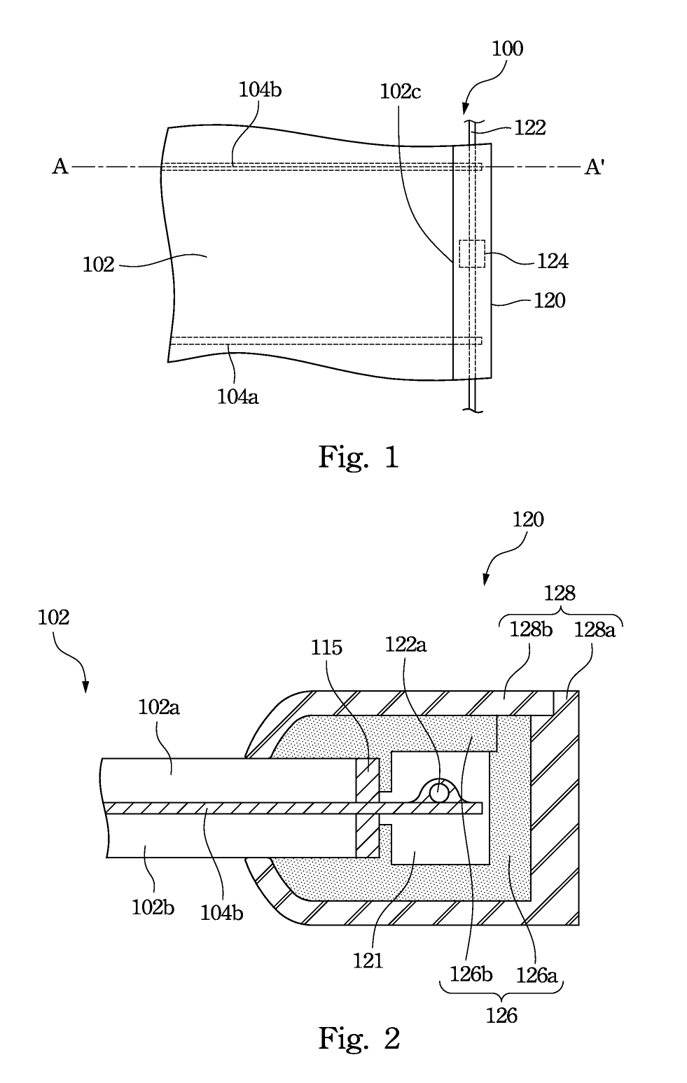

Referring to FIG. 1, a solar panel assembly 100 includes a solar panel 102 and at least two output terminals 104a and 104b extending from the solar panel for connection to an operating electronic device or a storage battery.

The solar panel 102 includes a photovoltaic film (not illustrated in drawings) to convert solar radiation into direct current electricity. A junction box 120 is attached to an edge 102c of the solar panel 102, from which the two output terminals (104a and 104b) extend out. In this embodiment, the junction box 120 and the edge 102c share an equal length. That is, the junction box 120 fully encloses the edge 102c of the solar panel 102. A power cable 122 may contain several sub-wires, each of which is electrically connected an end of the output terminals, e.g. 104a or 104b. A diode 124 may be installed as a component of the power cable 122 to prevent a reverse electric current from damaging the photovoltaic cells of the solar panel 102.

The junction box 120 can be designed to be elongate and arranged along the edge 102c of the solar panel 102 that its elongate axis is perpendicular to a direction along which the output terminals (104a or 104b) are arranged.

Referring to FIG. 2, a cross-sectional view taken along A-A′ of FIG. 1 is illustrated. The junction box 120 is integrated with the frame, which is used to hold an edge of the solar panel 102 and to be further supported by a base stand (not illustrated in the drawings). In particular, the junction box 120 includes an inner plastic case and an outer metal case (such as aluminum frame). The inner plastic case is an elongate plastic housing 126, which consists of an upper member 126b and a lower member 126a, so as to sandwich or clamp an edge of the solar panel 102. The upper member 126b is secured to an upper glass substrate 102a of the solar panel 102 by an adhesive 115. The lower member 126a is secured to a lower glass substrate 102b of the solar panel 102 by the adhesive 115. The upper member 126b and the lower member 126a are combined to define an inner passage 121 inside which a sub-wire 122a is soldered to an end of the output terminal 104b. Alternatively, the sub-wire 122a and the end of the output terminal 104b may be also electrically connected by clamping stand (not illustrated in the drawings) according to the demands. The elongate plastic housing 126 can be made from elastic plastic materials such that the elongate plastic housing 126 serves as a buffer member between two relatively hard materials, i.e. the glass substrate and the metal frame, such that the metal frame 128 would not damage the glass substrate (102a or 102b). The metal frame 128 also consists of two parts: a upper frame 128b and a lower frame 128a, which are assembled to fully enclose the elongate plastic housing 126 inside thereof.

In one embodiment, the lower member 126a is adhered onto the lower frame 128a to form an inverse L-shaped holder, and the upper member 126b is adhered onto the upper frame 128b to form an upper cover. Therefore, the inverse L-shaped holder and the upper cover are combined to define the passage 121 therein for accommodating the ends of the output terminals (104a and 104b), the diode 124 and the power cables 122.

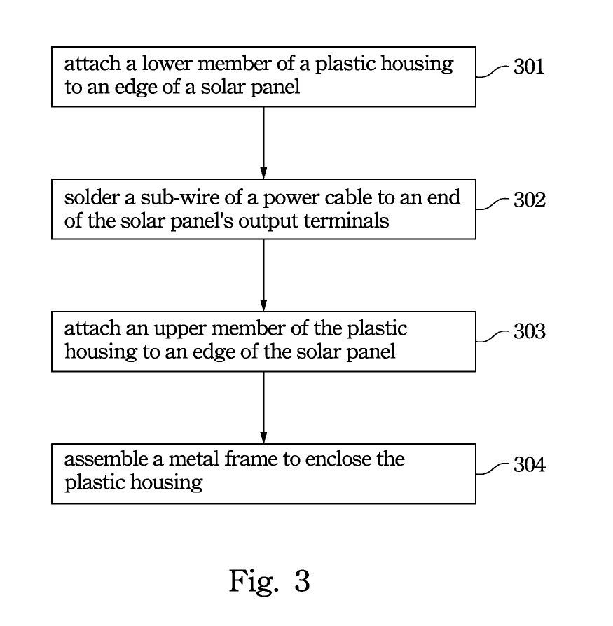

Referring to both FIG. 2 and FIG. 3, wherein FIG. 3 is a flowchart of a method for assembling a junction box to a solar panel according to one preferred embodiment of this invention.

In step 301, the lower member 126a of the plastic housing 126 is attached to the lower substrate 102b of the solar panel 102 by the adhesive 115. In this embodiment, the lower member 126a is to temporarily hold the output terminal 104b and the sub-wire 122a for the subsequent step 302.

In step 302, the sub-wire 122a of the power cable is soldered to an end of the output terminal 104b.

In step 303, the upper member 126a of the plastic housing 126 is attached to the upper substrate 102a of the solar panel 102 by the adhesive 115. Thus, an inner passage is defined by the upper and lower members (126a and 126b) to shield the soldered interconnection between the power cable and the output terminals of the solar panel. Besides, the edge of the solar panel 102 is sandwiched or clamped between the upper and lower members (126a and 126b).

In step 304, the upper frame 128b and the lower frame 128a are assembled to form a complete metal frame 128, which fully encloses the elongate plastic housing 126. The metal frame 128 may be anodized to form an outer protection layer (not illustrated in the drawings) so as to be anti-oxided.

In an alternate embodiment, the sequence for assembling a junction box to a solar panel can be: first, the inverse L-shaped holder consisting of the lower member 126a of the plastic housing and the lower frame 128a is attached to the lower substrate 102b of the solar panel 102 by the adhesive 115; second, the sub-wire 122a of the power cable is soldered to an end of the output terminal 104b; after that, the upper cover consisting of the upper member 126b of the plastic housing and the upper frame 128b is attached to the upper substrate 102a of the solar panel 102 by the adhesive 115. Accordingly, an accommodating passage 121 is defined for accommodating the soldered interconnection therein.

In this fashion, a durable junction box with relatively thin profile is provided for a solar panel, which protects the soldered power cable and output terminals from weather and water attacking.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A junction box for use in establishing electric connection between an electric cable and output terminals of a solar panel, the junction box comprising:
an elongate plastic housing disposed along and sandwiching an edge of the solar panel, from which the output terminals of a solar panel extends out, and defining a passage, inside which the electric cable is connected with the output terminals of the solar panel; and
a metal frame fully enclosing the elongate plastic housing.

2. The junction box of claim 1, wherein the elongate plastic housing comprises an elongate axis to be perpendicular to a direction along which the output terminals are disposed.

3. The junction box of claim 1, wherein the elongate plastic housing and the edge of the solar panel share an equal length.

4. The junction box of claim 1, wherein the elongate plastic housing consists of an upper member and a lower member, the solar panel is sandwiched between the upper and lower members.

5. The junction box of claim 4, wherein the upper member is secured to an upper glass substrate of the solar panel, the lower member is secured to a lower glass substrate of the solar panel.

6. The junction box of claim 1, wherein the elongate plastic housing is made from elastic plastic materials.

7. The junction box of claim 1, wherein the metal frame is made from aluminum.

8. The junction box of claim 1, wherein the metal frame consists of an upper frame and a lower frame.

9. A method for assembling a junction box to a solar panel comprising:
attaching a lower member of an elongate plastic housing to an edge of the solar panel;
soldering a sub-wire of a power cable to an end of output terminals of the solar panel;
attaching an upper member of the elongate plastic housing to the edge of the solar panel, the upper member and the lower member are combined to sandwich the soldered interconnection between the power cable and the output terminals of the solar panel; and
assembling a metal frame to fully enclose the elongate plastic housing.

10. The method of claim 9, further comprising:
attaching the lower member of the elongate plastic housing to an edge of a lower glass substrate of the solar panel.

11. The method of claim 9, further comprising:
using an adhesive to attach the lower member of the elongate plastic housing to the edge of the lower glass substrate of the solar panel.

12. The method of claim 9, further comprising:
attaching the upper member of the elongate plastic housing to an edge of a lower glass substrate of the solar panel.

13. The method of claim 12, further comprising:
using an adhesive to attach the upper member of the elongate plastic housing to the edge of the upper glass substrate of the solar panel.

14. The method of claim 9, wherein the elongate plastic housing is made from elastic plastic materials.

15. The method of claim 9, wherein the metal frame is made from aluminum.

16. The method of claim 9, further comprising:
arranging the elongate plastic housing to have an elongate axis thereof to be perpendicular to a direction along which the output terminals are disposed.
